(19) United States
(12) Patent Application Publication
(10) Pub. No.: US 2012/0017434 A1
(43) Pub. Date: Jan. 26, 2012

(54) METHOD AND APPARATUS FOR MANUFACTURING ELECTRONIC PAPER

(75) Inventors: Young Woo LEE, Suwon (KR); Sang Moon Lee, Seoul (KR); Hwan-Soo Lee, Seoul (KR); Jung Min Park, Suwon (KR)

(73) Assignee: SAMSUNG ELECTRO-MECHANICS CO., LTD.

(21) Appl. No.: 13/024,748

(22) Filed: Feb. 10, 2011

(30) Foreign Application Priority Data
Jul. 21, 2010 (KR) 10-2010-0070512

(51) Int. Cl. H05K 3/30

(52) U.S. Cl. 29/832

(57) ABSTRACT

There is provided a method of manufacturing electronic paper, the method including: preparing a substrate having a plurality of accommodating holes in order to accommodate electronic paper display elements; injecting insulating liquid into the individual accommodating holes; increasing the height of partitions forming the accommodating holes by mounting a mask on the partitions, the mask providing through-holes having a size similar to that of the accommodating holes; putting the electronic paper display elements into the accommodating holes; removing extra electronic paper display elements in excess of a predetermined number thereof by a removal unit in order that the predetermined number of electronic paper display elements are put into the accommodating holes; and removing the mask mounted on the partitions after the extra electronic paper display elements are removed from the accommodating holes.

### CROSS-REFERENCE TO RELATED APPLICATIONS

This application claims the priority of Korean Patent Application No. 2010-0070512 filed on Jul. 21, 2010, in the Korean Intellectual Property Office, the disclosure of which is incorporated herein by reference.

### BACKGROUND OF THE INVENTION

1. Field of the Invention

The present invention relates to a method and apparatus for manufacturing electronic paper, and more particularly, to a method and apparatus for manufacturing electronic paper in which electronic paper display elements are precisely aligned.

2. Description of the Related Art

In recent years, with the development of mobile information terminals or information communications networks, the development of display devices having superior portability and user-friendliness has been required. Among the display devices satisfying such requirements, electronic paper has been prominent.

Electronic paper has the following advantages: it has flexibility so that improved portability and user-friendliness are achieved; it can be driven with a low level of voltage and maintain high picture quality even after power is cut; and it has high resolution and a wide viewing angle.

Electronic paper includes transmissive electronic paper using a backlight as a light source, reflective electronic paper using sunlight as alight source rather than a backlight, and transflective electronic paper combining the transmissive electronic paper and the reflective electronic paper.

Proposed technical methods for the realization of electronic paper include the following approaches: a method of using liquid crystal, organic electroluminescent (EL) technology, an electrophoretic method, a method of using electronic paper display elements (e.g., twist balls), electrochromic technology, and the like. In the method of using electronic paper display elements, it is common that a plurality of electronic paper display elements differently colored with red, green or blue are arranged between two parallel light-transmissive sheets formed of elastomer (hereinafter, “elastomer matrix”).

Electronic paper display elements have optical and electrical anisotropy. That is, one hemisphere is charged with a negative charge and the other hemisphere is charged with a positive charge in such a manner as to form a permanent dipole. Also, the electronic paper display elements are coated with liquid to be rotatable in the elastomer matrix. That is, electronic paper using the electronic paper display elements may display a desired image by allowing the electronic paper display elements to be selectively rotatable when electricity is applied to the elastomer matrix.

In such electronic paper using the electronic paper display elements, it is important to arrange the electronic paper display elements having desired colors in desired positions of the elastomer matrix in a uniform manner so as to improve the definition of display screen.

However, the electronic paper using the electronic paper display elements may have shown degradation in display characteristics due to non-uniformity of the electronic paper display elements that may be caused in a process of disposing the electronic paper display elements in the elastomer matrix. Also, color display elements should be arranged in desired positions in order to manufacture a color display device, but it is difficult to selectively arrange the display elements in the elastomer matrix.

### SUMMARY OF THE INVENTION

An aspect of the present invention provides a method of manufacturing electronic paper allowing electronic paper display elements having desired colors to be injected into predetermined positions in a substrate having a plurality of accommodating holes, with the use of a mask allowing the electronic paper display elements to pass therethrough.

An aspect of the present invention also provides a method of manufacturing electronic paper allowing for a reduction of manufacturing costs by simplifying the alignment of electronic paper display elements with the use of a mask sheet, and mass production.

According to an aspect of the present invention, there is provided a method of manufacturing electronic paper, the method including: preparing a substrate having a plurality of accommodating holes in order to accommodate electronic paper display elements; injecting insulating liquid into the individual accommodating holes; heating and evaporating the insulating liquid injected into the accommodating holes while leaving a portion of the insulating liquid; and disposing the electronic paper display elements in the accommodating holes.

The disposing of the electronic paper display elements may be performed by mounting a mask on the substrate so as to align the accommodating holes of the substrate and through-holes of the mask, and putting the electronic paper display elements into the accommodating holes through the through-holes of the mask.

The method may further include removing extra electronic paper display elements.

The removing of the extra electronic paper display elements may be performed by causing the extra electronic paper display elements to be attached to an adsorbing roller.

The electronic paper display elements may be twist balls or micro capsules.

The method may further include cleaning the adsorbing roller having the extra electronic paper display elements attached thereto.

According to another aspect of the present invention, there is provided an apparatus for manufacturing electronic paper, the apparatus including: a substrate stage having a substrate mounted thereon, the substrate having accommodating holes in which electronic paper display elements are accommodated; a supply unit supplying the electronic paper display elements in order to put the electronic paper display elements into the accommodating holes of the substrate; and a heating device provided in the substrate stage and evaporating insulating liquid injected into the accommodating holes while leaving a portion of the insulating liquid.

The apparatus may further include an image device checking a remaining amount of the insulating liquid injected into the accommodating holes.

The supply unit may include a brush allowing the electronic paper display elements to be attached thereto by static electricity and putting the electronic paper display elements into the individual accommodating holes.

The brush may include an ultrasonic vibration plate.

The substrate stage may include a base having a vacuum state therein; a plate mounted on the base and having the substrate mounted thereon; and an outlet discharging air of the base and allowing the substrate and the plate to be tightly fixed due to the vacuum state.

According to another aspect of the present invention, there is provided an apparatus for manufacturing electronic paper, the apparatus including: a substrate stage having a substrate mounted thereon, the substrate having an accommodating hole in which an electronic paper display element is accommodated; a supply unit supplying the electronic paper display element in order to put the electronic paper display element into the accommodating hole of the substrate; a mask stage providing a mask mounted on the substrate and having a through-hole formed therein; a moving unit moving the substrate stage so as to align the accommodating hole of the substrate and the through-hole of the mask; and a control unit controlling a moving direction of the moving unit.

The apparatus may further include a monitor unit monitoring positions of the accommodating hole of the substrate and the through-hole of the mask so as to align the accommodating hole and the through-hole.

The supply unit or the monitor unit may be controlled by the control unit.

According to another aspect of the present invention, there is provided an apparatus for manufacturing electronic paper, the apparatus including: a substrate stage having a substrate mounted thereon, the substrate having an accommodating hole in which an electronic paper display element is accommodated; a supply unit supplying the electronic paper display element in order to put the electronic paper display element into the accommodating hole of the substrate; and a removal unit removing an extra electronic paper display element.

The removal unit may be an adsorbing roller removing the extra electronic paper display element by causing the extra electronic paper display element to be attached thereto.

The apparatus may further include a cleaning unit cleaning the adsorbing roller.

The cleaning unit may include an adhesive film allowing the extra electronic paper display element to be adhered thereto; and a tacky roller having the adhesive film wound thereon.

The cleaning unit may include a spray device spraying liquid for removing the extra electronic paper display element attached to the adsorbing roller on the adsorbing roller; a chamber containing the liquid dropped from the adsorbing roller; and a net provided in the chamber so as to filter the liquid and the electronic paper display element.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic view illustrating a system for mounting electronic paper display elements according to an exemplary embodiment of the present invention;

FIG. 2A is a cross-sectional view illustrating a substrate stage according to an exemplary embodiment of the present invention;

FIG. 2B is a cross-sectional view illustrating a substrate stage according to an exemplary embodiment of the present invention;

FIG. 2C is a cross-sectional view illustrating a substrate stage according to an exemplary embodiment of the present invention;

FIGS. 3A through 3I are schematic views illustrating a process of mounting electronic paper display elements according to an exemplary embodiment of the present invention; and

FIGS. 4A and 4B are schematic cross-sectional views illustrating a system for cleaning a removal unit.

### DETAILED DESCRIPTION OF THE PREFERRED EMBODIMENT

Exemplary embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements or components may be exaggerated for clarity.

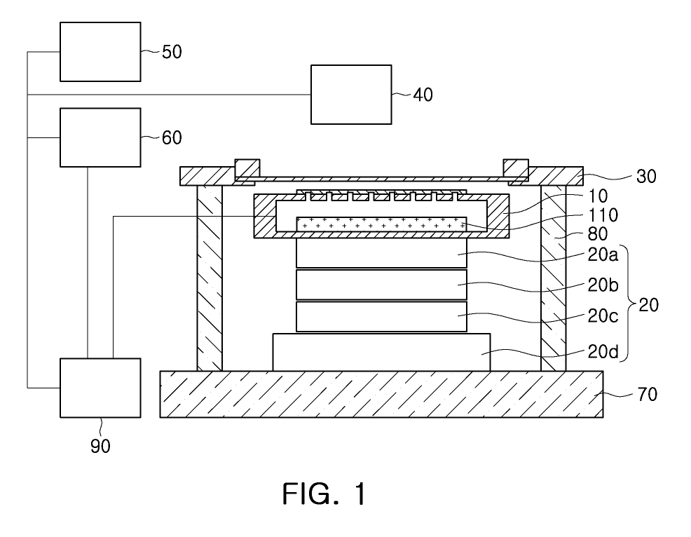

FIG. 1 is a schematic view illustrating a system for mounting electronic paper display elements according to an exemplary embodiment of the present invention.

With reference to FIG. 1, an apparatus for manufacturing electronic paper according to an exemplary embodiment of the invention includes a substrate stage 10, a moving unit 20, a mask stage 30, a monitor unit 40, a supply unit 50, a removal unit 60, a support unit 70, and a control unit 90.

The substrate stage 10 has a substrate mounted thereon in order to accommodate electronic paper display elements. The substrate has micro-cups formed therein. The electronic paper display elements are accommodated in the individual micro-cups.

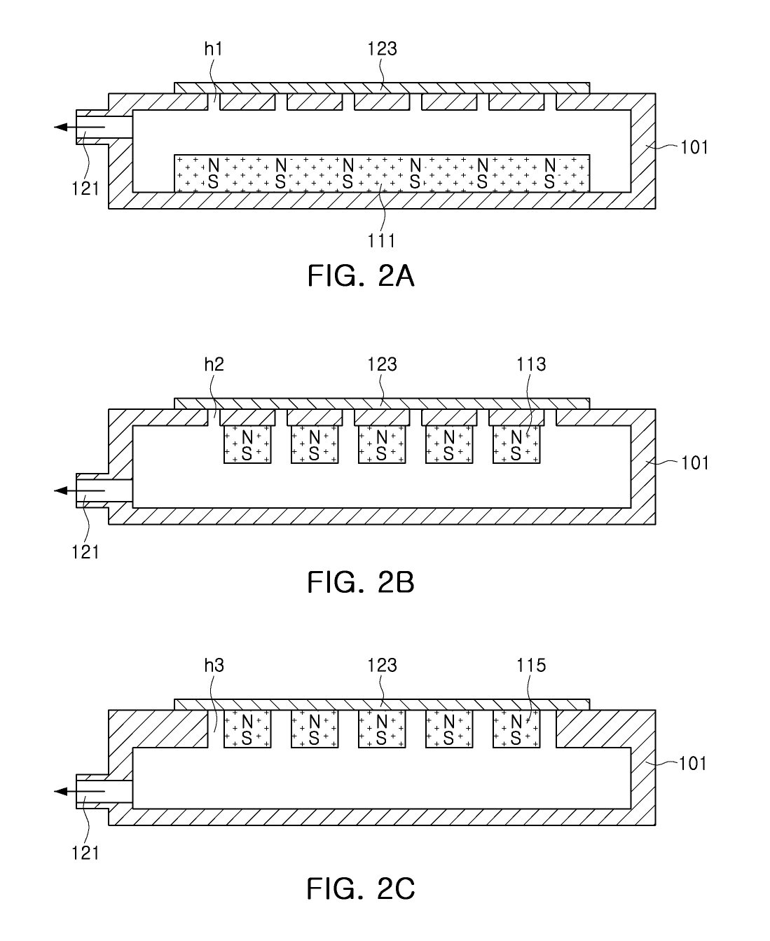

The substrate stage 10, including a plate 123, an outlet 121 and a magnet 110, will be described in detail with reference to FIGS. 2A through 2C.

The apparatus for manufacturing the electronic paper according to the exemplary embodiment of the invention includes the moving unit 20 moving the substrate stage 10. The moving unit 20 may include at least one of an x-axis moving portion 20a, a y-axis moving portion 20b, a z-axis moving portion 20c, and a θ-directional moving portion 20d.

The moving unit 20 is provided to move the substrate stage 10. The x-axis moving portion 20a moves the substrate in a horizontal manner in an x-axis direction and the y-axis moving portion 20b moves the substrate in a horizontal manner in a y-axis direction. Also, the z-axis moving portion 20c moves the substrate in a vertical manner in a z-axis direction. The θ-direction moving portion 20d adjusts the angle of the substrate.

The moving unit 20 is controlled by the control unit 90 so that the moving unit 20 may move the substrate to a desired position.

The apparatus for manufacturing the electronic paper according to the exemplary embodiment of the invention includes the mask stage 30. In this embodiment, in order to increase the height of partitions forming accommodating holes of the substrate, a mask is mounted on the partitions. The mask has through-holes corresponding to the sizes of the accommodating holes of the substrate, and the through-holes are aligned to have a pattern similar to that of the substrate. Accordingly, when the mask is mounted on the substrate by allowing for the matching of the through-holes of the mask and the accommodating holes of the substrate, the height of the partitions of the substrate is increased.

As the height of the partitions of the substrate is increased, the electronic paper display elements may be precisely accommodated in desired positions of the substrate.

The mask stage 30 accommodates the mask and fixes the mask to the substrate. The mask stage 30 is fixed by the support unit 70 provided thereunder.

The apparatus for manufacturing the electronic paper according to the exemplary embodiment of the invention includes the monitor unit 40 monitoring the positions of the mask and the substrate for the arrangement thereof. The monitor unit 40 may include two or more cameras.

The monitor unit 40 may be positioned above the mask stage 30 to match the positions of the through-holes of the mask with the accommodating holes of the substrate. In order to match the positions of the through-holes with the accommodating holes, the position of the substrate may be adjusted by the moving unit 20.

The moving unit 20 and the monitor unit 40 may be used to place the mask in a precise position of the substrate allowing for the matching of the through-holes and the accommodating holes. The monitor unit 40 may monitor the alignment of the through-holes and the accommodating holes by the use of the two or more cameras.

Also, the moving unit 20 and the monitor unit 40 may be controlled by the control unit 90 in order that the mask may be placed in the precise position.

The apparatus for manufacturing the electronic paper according to the exemplary embodiment of the invention includes the supply unit 50 supplying the electronic paper display elements.

The supply unit 50 may supply the electronic paper display elements such as twist balls or micro capsules. The electronic paper display elements are supplied after the mask is mounted on the substrate.

The supply unit 50 may include a brush 51. The electronic paper display elements may be attached to the brush 51 by static electricity or the like.

After the electronic paper display elements are attached to the brush 51, the electronic paper display elements may be supplied to the substrate attached with the mask by causing the electronic paper display elements to contact the substrate.

When the brush 51 having the electronic paper display elements attached thereto contacts a surface of the mask mounted on the substrate, the brush 51 is subjected to a rotary motion in vertical and horizontal manners so that the electronic paper display elements may be put into the individual accommodating holes. In order to provide further vibrations to the brush 51, an ultrasonic vibration plate (not shown) may be connected to the brush 51.

The electronic paper display elements attached to the brush 51 by static electricity may be accommodated in the accommodating holes formed by the high partitions due to the surface tension of insulating liquid such as oil provided within the accommodating holes.

Also, the apparatus for manufacturing the electronic paper according to the exemplary embodiment of the invention includes the removal unit 60 removing the electronic paper display elements.

When the electronic paper display elements are accommodated in the accommodating holes formed by the partitions having the increased height due to the mask as described above, it is necessary to remove extra electronic paper display elements in excess of a predetermined number thereof in order to accommodate only the predetermined number of electronic paper display elements.

In order to remove the extra electronic paper display elements, the removal unit 60 may include an adsorbing roller 61.

The height of the partitions formed on the substrate is determined to allow for the accommodation of the predetermined number of electronic paper display elements. The invention is not particularly limited, but the height of the partitions of the accommodating hole may be similar to the height of one electronic paper display element in order to mount the one electronic paper display element in one accommodating hole. Therefore, the partitions have the height allowing the one accommodating hole to accommodate the one electronic paper display element.

Accordingly, when the mask is mounted on the substrate, upper portions of the extra electronic paper display elements are exposed to the outside.

Herein, when the adsorbing roller 61 passes on the substrate attached with the mask, the extra electronic paper display elements having the exposed upper portions are attached to the adsorbing roller 61 to be thereby removed.

The movements of the removal unit 60, such as the adsorbing roller 61, may also be controlled by the control unit 90.

Also, the apparatus for manufacturing the electronic paper according to the exemplary embodiment of the invention may further include the support unit 70 supporting the mask stage 30 and the substrate stage 10.

The support unit 70 may include a vibration absorbing portion (not shown) absorbing vibrations caused by the movements of the substrate or the like.

The apparatus for manufacturing the electronic paper according to the exemplary embodiment of the invention may further include the control unit 90. The control unit 90 may be controllable by a user or a computer.

The control unit 90 may control the moving unit 20 as well as the supply unit 50, the removal unit 60 or the monitor unit 40 in order to control the process of accommodating the electronic paper display elements in the accommodating holes of the substrate.

FIGS. 2A through 2C are cross-sectional views illustrating the substrate stage 10 according to exemplary embodiments of the present invention.

With reference to FIGS. 2A through 2C, the substrate stage 10 includes a base 101, the plate 123, grooves h, the outlet 121, and a magnet 111, 113 and 115.

The plate 123 is disposed on the base 101 and has the substrate mounted thereon, in which the substrate accommodates the electronic paper display elements.

The magnet 111, 113 and 115 is mounted inside the base 101. When the substrate is mounted on the plate 123, the magnet 111, 113 and 115 serves to fix the mask thereto.

The mask may be formed of a ferromagnetic material. Accordingly, the magnet 111, 113 and 115 formed in the substrate stage 10 attracts the mask with magnetic force, and thus allows the mask to be fixed to the substrate.

The grooves h and the outlet 121 are formed in the base 101. The outlet 121 includes a vacuum pump so that the outlet 121 may pump air out.

The plate 123 also has grooves formed therein so that air circulation between the outside and the base 101 may occur.

In this manner, when the substrate is disposed on the plate 123, the grooves are blocked. When the air within the base 101 is discharged through the outlet 121, the base 101 is in a vacuum state, and accordingly, the substrate mounted on the plate 123 is tightly fixed due to the vacuum state.

The substrate is mounted on the flat plate 123 and tightly fixed thereto due to the vacuum state, so that the flatness thereof within tens of millimeters or less may be ensured.

Also, the substrate stage 10 may further include a heating device (not shown) in order to evaporate the insulating liquid contained in the substrate.

The magnet and the outlet may be positioned in various manners. FIGS. 2A through 2C are cross-sectional views illustrating a substrate stage in which a magnet and an outlet are formed in various manners according to exemplary embodiments of the invention.

FIG. 2A is a cross-sectional view illustrating a substrate stage according to an exemplary embodiment of the invention. According to the embodiment illustrated in FIG. 2A, the outlet 121 is formed in the upper end of the base 101 and the magnet 111 is formed on the lower surface of the inside of the base 101.

FIG. 2B is a cross-sectional view illustrating a substrate stage according to an exemplary embodiment of the invention. According to the embodiment illustrated in FIG. 2B, the outlet 121 is formed in the lower end of the base 101 and the magnet 113 is formed on the upper surface of the inside of the base 101.

FIG. 2C is a cross-sectional view illustrating a substrate stage according to an exemplary embodiment of the invention. According to the embodiment illustrated in FIG. 2C, the outlet 121 is formed in the lower end of the base 101 and the magnet 115 is formed on the lower surface of the plate 123 since the base 101 has an open top portion.

In an exemplary embodiment of the present invention, a north pole may be disposed towards the substrate. The invention is not limited thereto, so long as the magnet is disposed to provide magnetic force to the mask mounted on the mask stage 30.

In another exemplary embodiment of the invention, a south pole may be disposed towards the substrate, which is not shown.

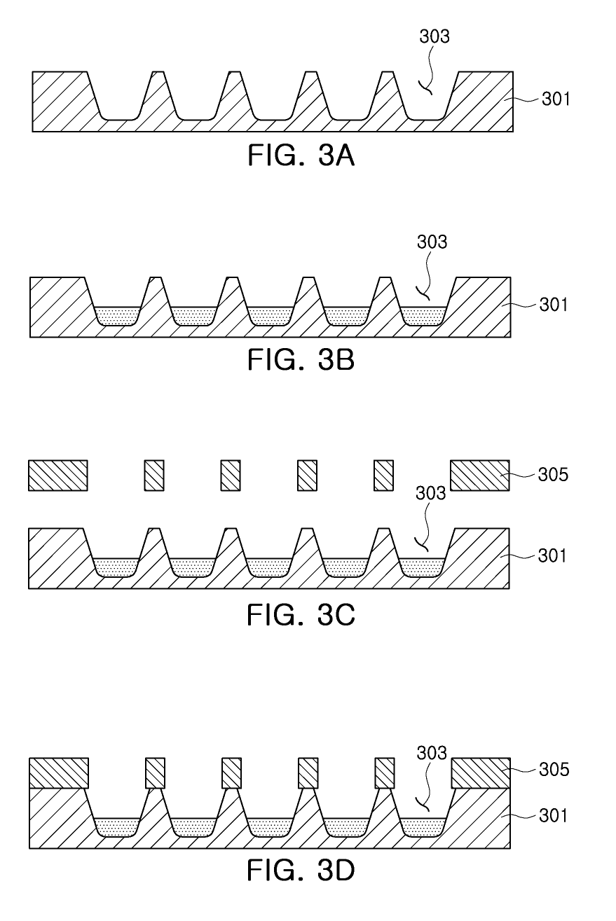

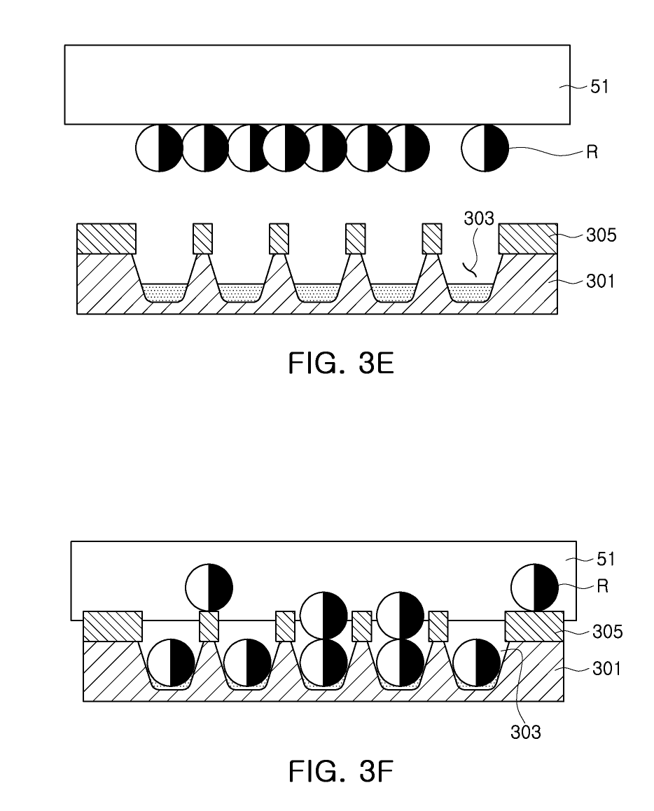

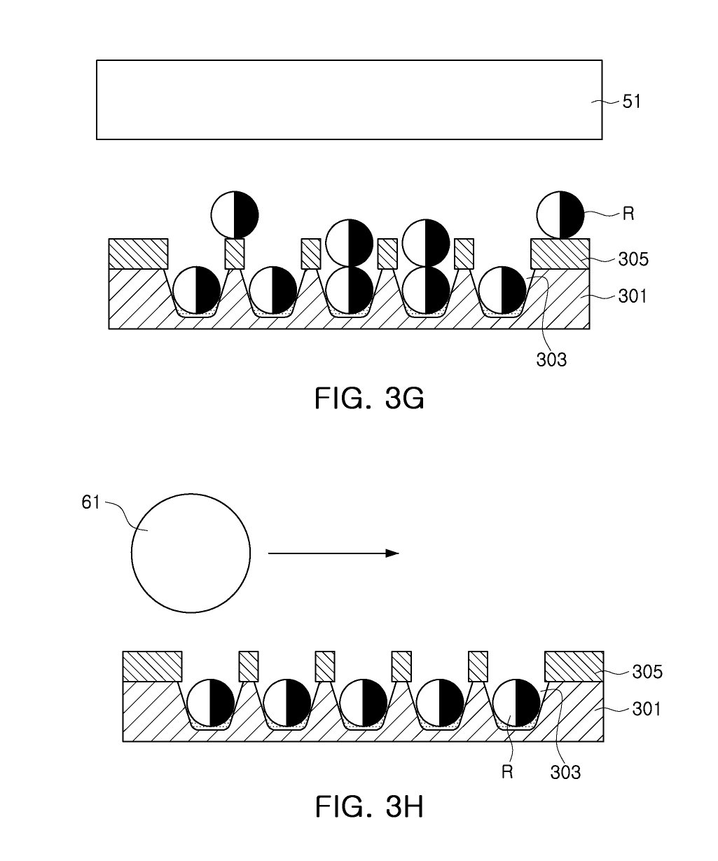

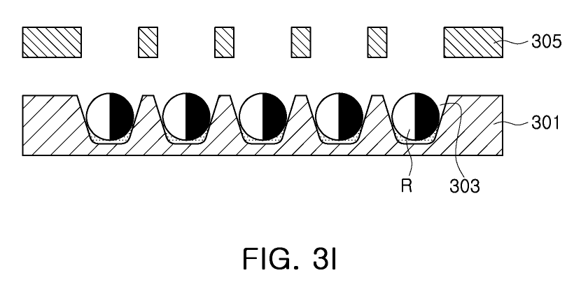

FIGS. 3A through 3I are schematic views illustrating a process of mounting electronic paper display elements according to an exemplary embodiment of the invention.

FIG. 3A illustrates a substrate 301 mounted on the substrate stage 10. The substrate 301 may have a plurality of accommodating holes 303 in order to accommodate electronic paper display elements in light-transmissive sheets such as an elastomer matrix, but is not limited thereto.

The accommodating hole 303 according to an exemplary embodiment of the invention may have the form of a micro-cup. The micro-cup may selectively have an electronic paper display element having a desired color mounted therein.

In order to mount one electronic paper display element in the micro cup, the individual accommodating holes 303 may have a size allowing for the accommodation of one electronic paper display element. However, the invention is not limited thereto.

With reference to FIG. 3B, the accommodating holes 303 are filled with insulating liquid such as oil. The insulating liquid is used in accommodating the electronic paper display elements with surface tension. The substrate is not fully filled with oil, but with an amount of oil allowing for the formation of appropriate surface tension.

In order to fill the accommodating holes 303 with the amount of insulating liquid allowing for the formation of appropriate surface tension, the insulating liquid is fully injected into the accommodating holes 303, and then the oil remaining on the surface of the substrate is removed by a squeezer.

In an exemplary embodiment of the invention, a heating device may be further included in the substrate stage 10. The heating device may evaporate the insulating liquid that is present inside the substrate to cause the appropriate amount of the insulating liquid to be present therein.

An image device (not shown) such as an optical microscope may be used to check a reflective band, thereby checking the amount of the insulating liquid.

In order to mount the electronic paper display elements in the substrate 301, the substrate 301 is firstly cleaned in order that no impurity is present on the surface of the substrate 301.

In an exemplary embodiment of the invention, the substrate 301 is immersed in a liquid formed of a solvent including alcohol and a detergent, and is then cleaned by the use of ultrasonic waves to thereby remove the impurities from the substrate.

The invention is not limited thereto. The substrate may be cleaned by a detergent and then dried, and accordingly, the impurities may be removed from the surface of the substrate.

After the substrate is cleaned, the accommodating holes 303 formed in the substrate 301 are filled with the insulating liquid such as oil.

However, in the case in which the accommodating holes are fully filled with the insulating liquid, this interferes with the mounting of the electronic paper display elements. Therefore, it is necessary to leave only the amount of the insulating liquid required for providing surface tension to the surface of the electronic paper display element.

In an exemplary embodiment of the invention, the oil remaining on the surface of the substrate is removed by the squeezer, and the oil contained in the accommodating holes 303 is evaporated by the heating device, so that the required amount of oil remains.

At this time, the remaining amount of the oil contained in the accommodating hole 303 is controlled by which a diameter of the reflective band formed in the accommodating hole 303 is checked through an optical microscope (not shown).

FIGS. 3C and 3D illustrate mounting the substrate 301 having the appropriate amount of oil contained therein on the substrate stage 10 and mounting a mask 305 thereon.

In order to mount the substrate 301 on the substrate stage 10, the substrate 301 may be positioned on the base 101 of the substrate stage 10. When the substrate 301 is positioned on the base 101, a vacuum state inside the base 101 is formed by the outlet 121, and accordingly, the substrate 301 may be fixed to the plate 123.

Since the substrate 301 is fixed to the plate 123, the flatness thereof within tens of millimeters or less may be ensured.

After the substrate 301 is mounted on the substrate stage 10, the mask 305 provided on the mask stage 30 may be mounted on the substrate 301.

In order to adjust the positions of the accommodating holes 303 formed in the substrate 301 and the through-holes formed in the mask 305, the position of the substrate is adjusted to match the positions of the accommodating holes 303 with the through-holes.

In this manner, the depth of the accommodating holes 303 of the substrate 301 is increased, so that the electronic paper display elements are prevented from crossing over the mask and the substrate and moving to another position. That is, it is easy to allow an electronic paper display element having a desired color to be arranged in a desired position in the substrate.

The mask may be formed of a ferromagnetic material such as Fe, Co, Ni and an alloy thereof, but is not limited thereto. Accordingly, the mask is affected by a magnetic field generated by the magnet formed in the substrate stage 10.

When the positions of the accommodating holes 303 of the substrate 301 and the through-holes of the mask 305 are arranged and the substrate 301 is disposed in a desired position, the mask 305 formed of the ferromagnetic material is drawn by the magnetic force generated by the magnet, e.g., a permanent magnet, formed in the substrate stage 10.

In this manner, the mask 305 is mounted on the partitions of the accommodating holes 303.

FIGS. 3F and 3G illustrate mounting the electronic paper display elements in the substrate.

Electronic paper display elements R are supplied to the substrate 301 having the mask 305 mounted thereon by the supply unit 50 such as the brush 51.

For example, the electronic paper display elements R are attached to the brush 51 by static electricity, and the brush 51 having the electronic paper display elements R attached thereto contacts the surface of the mask 305.

When the brush 51 is subjected to a rotary motion in vertical and horizontal manners, the electronic paper display elements R attached to the brush 51 by the static electricity are put into the accommodating holes 303 in a manner such that the electronic paper display elements R are attached to the insulating liquid due to the surface tension of the insulating liquid provided in the accommodating holes 303.

In order to facilitate the mounting of the electronic paper display elements R by providing further vibrations to the brush 51, an ultrasonic vibration plate (not shown) may be connected to the brush 51 and provide the vibrations thereto.

FIG. 3H illustrates removing extra electronic paper display elements by the removal unit 60 such as the adsorbing roller 61.

With reference to FIGS. 3F and 3G, one or two electronic paper display elements are mounted in one accommodating hole.

In an exemplary embodiment of the invention, the individual accommodating holes 303 are formed to have a size suitable for accommodating one electronic paper display element, and the mask 305 is formed to have a height allowing for the removal of extra electronic paper display elements. That is, since the height of the mask 305 is lower than that of the one electronic paper display element, when the extra electronic paper display elements are mounted in the accommodating holes 303, the upper portions of the extra electronic paper display elements are exposed to the outside.

The extra electronic paper display elements are removed by the removal unit 60 such as the adsorbing roller 61. Since the upper portions of the extra electronic paper display elements are exposed to the outside, when the removal unit 60 such as the adsorbing roller 61 passes on the upper surface of the mask 305, the extra electronic paper display elements are attached to the adsorbing roller 61. However, the electronic paper display elements disposed in the lower portions of the accommodating holes remain due to the surface tension of the insulating liquid without being attached to the adsorbing roller 61.

In this manner, only the predetermined number of electronic paper display elements remain in the accommodating holes 303, and the extra electronic paper display elements are removed by the removal unit 60.

FIG. 3I illustrates removing the mask 305 when the predetermined number of electronic paper display elements are mounted in the substrate 301, thereby manufacturing electronic paper.

When the predetermined number of electronic paper display elements are accommodated in the accommodating holes 303 of the substrate 301, the mask 305 is separated from the substrate 301 in order to manufacture the electronic paper.

Since the mask 305 is attached to the substrate 301 by the magnet 110, e.g., a permanent magnet, formed in the substrate stage 10, the mask 305 may be removed by magnetic force.

Then, the substrate having the predetermined number of electronic paper display elements mounted in predetermined positions may be obtained, and the electronic paper employing this substrate may be manufactured.

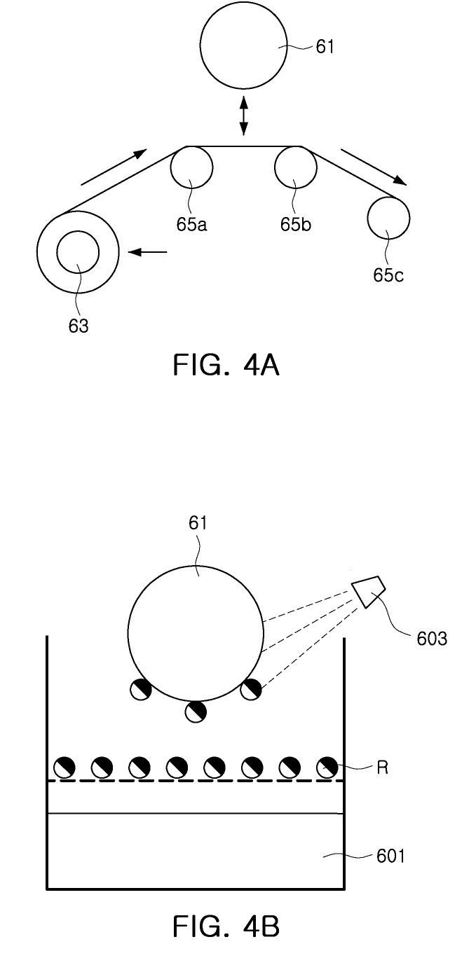

FIGS. 4A and 4B are schematic cross-sectional views illustrating a system for cleaning a removal unit according to an exemplary embodiment of the present invention.

After the substrate having the predetermined number of electronic paper display elements mounted in the predetermined positions is manufactured, the adsorbing roller 61 may be cleaned and reused.

In an exemplary embodiment of the invention, the extra electronic paper display elements attached to the adsorbing roller 61 may be removed by the use of an adhesive sheet such as an viscosity film and a cleaning roller 63 such as a viscosity roller as shown in FIG. 4A in a manner such that they may be attached to the adhesive sheet. After the extra electronic paper display elements are removed from the adsorbing roller 61, the adsorbing roller 61 may be reused in the mounting of electronic paper display elements.

In another exemplary embodiment of the invention, the electronic paper display elements R attached to the adsorbing roller 61 may be removed by spraying a solvent such as alcohol thereon through a spray device 603. The solvent sprayed on the electronic paper display elements R drops into a chamber 601 having a net formed therein. In this manner, the electronic paper display elements R may be left on the net and the solvent may drop into the chamber 601.

The electronic paper display elements R left on the net and the adsorbing roller 61 may be cleaned by a cleaning unit and then be reused.

As set forth above, in a method of manufacturing electronic paper according to exemplary embodiments of the invention, a plurality of electronic paper display elements having desired colors may be aligned in desired positions.

Also, in a method of manufacturing electronic paper according to exemplary embodiments of the invention, the alignment of electronic paper display elements is simplified with the use of a mask sheet so that a reduction of manufacturing costs and mass production may be achieved.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of manufacturing electronic paper, the method comprising:
preparing a substrate having a plurality of accommodating holes in order to accommodate electronic paper display elements;
injecting insulating liquid into the individual accommodating holes;
heating and evaporating the insulating liquid injected into the accommodating holes while leaving a portion of the insulating liquid; and
disposing the electronic paper display elements in the accommodating holes.

2. The method of claim 1, wherein the disposing of the electronic paper display elements is performed by mounting a mask on the substrate so as to align the accommodating holes of the substrate and through-holes of the mask, and putting the electronic paper display elements into the accommodating holes through the through-holes of the mask.

3. The method of claim 1, further comprising removing extra electronic paper display elements.

4. The method of claim 3, wherein the removing of the extra electronic paper display elements is performed by causing the extra electronic paper display elements to be attached to an adsorbing roller.

5. The method of claim 1, wherein the electronic paper display elements are twist balls or micro capsules.

6. The method of claim 4, further comprising cleaning the adsorbing roller having the extra electronic paper display elements attached thereto.

7. An apparatus for manufacturing electronic paper, the apparatus comprising:
a substrate stage having a substrate mounted thereon, the substrate having accommodating holes in which electronic paper display elements are accommodated;
a supply unit supplying the electronic paper display elements in order to put the electronic paper display elements into the accommodating holes of the substrate; and
a heating device provided in the substrate stage and evaporating insulating liquid injected into the accommodating holes while leaving a portion of the insulating liquid.

8. The apparatus of claim 7, further comprising an image device checking a remaining amount of the insulating liquid injected into the accommodating holes.

9. The apparatus of claim 7, wherein the supply unit is a brush allowing the electronic paper display elements to be attached thereto by static electricity and putting the electronic paper display elements into the individual accommodating holes.

10. The apparatus of claim 9, wherein the brush comprises an ultrasonic vibration plate.

11. The apparatus of claim 7, wherein the substrate stage comprises:
a base having a vacuum state therein;
a plate mounted on the base and having the substrate mounted thereon; and
an outlet discharging air of the base and allowing the substrate and the plate to be tightly fixed due to the vacuum state.

12. An apparatus for manufacturing electronic paper, the apparatus comprising:
a substrate stage having a substrate mounted thereon, the substrate having an accommodating hole in which an electronic paper display element is accommodated;
a supply unit supplying the electronic paper display element in order to put the electronic paper display element into the accommodating hole of the substrate;
a mask stage providing a mask mounted on the substrate and having a through-hole formed therein;
a moving unit moving the substrate stage so as to align the accommodating hole of the substrate and the through-hole of the mask; and
a control unit controlling a moving direction of the moving unit.

13. The apparatus of claim 12, further comprising a monitor unit monitoring positions of the accommodating hole of the substrate and the through-hole of the mask so as to align the accommodating hole and the through-hole.

14. The apparatus of claim 13, wherein the supply unit or the monitor unit is controlled by the control unit.

15. An apparatus for manufacturing electronic paper, the apparatus comprising:
a substrate stage having a substrate mounted thereon, the substrate having an accommodating hole in which an electronic paper display element is accommodated;
a supply unit supplying the electronic paper display element in order to put the electronic paper display element into the accommodating hole of the substrate; and
a removal unit removing an extra electronic paper display element.

16. The apparatus of claim. 15, wherein the removal unit is an adsorbing roller removing the extra electronic paper display element by causing the extra electronic paper display element to be attached thereto.

17. The apparatus of claim 16, further comprising a cleaning unit cleaning the adsorbing roller.

18. The apparatus of claim 17, wherein the cleaning unit comprises:
an adhesive film allowing the extra electronic paper display element to be adhered thereto; and
a viscosity roller having the adhesive film wound thereon.

19. The apparatus of claim 17, wherein the cleaning unit comprises:
a spray device spraying liquid for removing the extra electronic paper display element attached to the adsorbing roller on the adsorbing roller;
a chamber containing the liquid dropped from the adsorbing roller; and
a net provided in the chamber so as to filter the liquid and the electronic paper display element.
